(19) United States
(12) Patent Application Publication
(10) Pub. No.: US 2025/0246835 A1
(43) Pub. Date: Jul. 31, 2025

(54) Electrical Connector Assembly

(71) Applicant: Caterpillar Inc., Peoria, IL (US)

(72) Inventor: Alexander DOWLING, Park Grove (AU)

(73) Assignee: Caterpillar Inc., Peoria, IL (US)

(21) Appl. No.: 19/039,483

(22) Filed: Jan. 28, 2025

(30) Foreign Application Priority Data
Jan. 29, 2024 (AU) 2024200527

(51) Int. Cl. H01R 13/00; B60L 53/80; H01R 13/533

(52) U.S. Cl. CPC H01R 13/005; B60L 53/80; H01R 13/533; B60L 2200/40; H01R 2201/26

(57) ABSTRACT

An electrical connector assembly for establishing an electrical connection includes an electrical connector adapted to couple with an electrical component. The electrical connector includes at least one connector plate. The electrical connector also includes a plurality of connecting terminals disposed in the at least one connector plate. The electrical connector further includes a cooling circuit disposed around one or more of the plurality of connecting terminals. The cooling circuit includes one or more fluid passages. The one or more fluid passages are adapted to receive a fluid flow to cool the at least one connector plate.

### TECHNICAL FIELD

The present disclosure relates to an electrical connector assembly for establishing an electrical connection, a machine having the electrical connector assembly, and a method of cooling an electrical connector of the electrical connector assembly.

### BACKGROUND

Many machines now incorporate battery systems as their main source of operating power. It may be required to replenish/recharge the battery system, based on operation of the machine. Further, it may be desirable to quickly and conveniently replenish the battery system to continue machine operations. However, current battery charging technologies cannot achieve charging within a few minutes similar to refueling. Therefore, battery replacement has become an efficient and convenient method to get a machine up and running after depletion of energy from the battery system. The battery system may also have to be replaced in case of a failure of the battery system.

Further, a high-voltage connector electrically connects the battery system with one or more machine components. Due to high discharge rates of the machines, the high-voltage connector is prone to act as a heat sink as it experiences higher resistance at the interface. Further, in order to discharge heat away from the high-voltage connector during the battery swap, a length of a cable associated with the high-voltage connector may have to be increased or an oversize high-voltage connector may have to be used, which may increase cost and complexity associated with such high-voltage connectors. Thus, an improved mechanism is needed to address the issue of thermal discharge, especially, during high-voltage battery swap for battery operated machines.

Chinese Utility Model Number CN215204395U discloses a power battery module to chassis (MTC) system. According to the power battery MTC system provided by the utility model, the battery module mounting groove is formed in the new energy vehicle frame, the mounting channel and the locking mechanism are arranged in the mounting groove, the lifting lug is arranged on the battery module, and the lifting lug can quickly enter the locking mechanism through the mounting channel, so that the battery module can be quickly mounted on the vehicle frame. A liquid cooling system and a high-low voltage system are redesigned, the high-low voltage system is provided with a high-voltage quick-plug connector and a low-voltage quick-plug connector, and the liquid cooling system is provided with a liquid cooling quick-plug connector, so that quick-plug connection of the battery module with the high-low voltage system and the liquid cooling system in the process of mounting the battery module on a frame is realized. According to the utility model, a pack box body is removed, so that the weight of the whole vehicle is reduced, and the investment of materials, manpower and equipment is reduced. And when the battery module breaks down, the battery module can be quickly replaced or maintained, and the remaining modules can be reconnected to form a power system after the faulted module is disassembled, so that the effects of lower later maintenance cost, more convenience and quickness are achieved.

### SUMMARY OF THE DISCLOSURE

In an aspect of the present disclosure, an electrical connector assembly for establishing an electrical connection is provided. The electrical connector assembly includes an electrical connector adapted to couple with an electrical component. The electrical connector includes at least one connector plate. The electrical connector also includes a plurality of connecting terminals disposed in the at least one connector plate. The electrical connector further includes a cooling circuit disposed around one or more of the plurality of connecting terminals. The cooling circuit includes one or more fluid passages. The one or more fluid passages are adapted to receive a fluid flow to cool the at least one connector plate.

In another aspect of the present disclosure, a machine is provided. The machine includes an electrical component. The machine also includes an electrical connector coupled with the electrical component. The electrical connector assembly includes an electrical connector adapted to couple with the electrical component. The electrical connector includes at least one connector plate. The electrical connector also includes a plurality of connecting terminals disposed in the at least one connector plate. The electrical connector further includes a cooling circuit disposed around one or more of the plurality of connecting terminals. The cooling circuit includes one or more fluid passages. The one or more fluid passages are adapted to receive a fluid flow to cool the at least one connector plate.

In yet another aspect of the present disclosure, a method of cooling an electrical connector of a machine is provided. The electrical connector is adapted to be coupled with an electrical component of the machine. The method includes providing the electrical connector. The electrical connector includes at least one connector plate, a plurality of connecting terminals disposed in the at least one connector plate, and a cooling circuit disposed around one or more of the plurality of connecting terminals. The cooling circuit includes one or more fluid passages. The one or more fluid passages are adapted to receive a fluid flow to cool the at least one connector plate. The method also includes providing a cooling system in fluid communication with the cooling circuit. The method further includes controlling the cooling system to selectively supply the fluid flow towards the one or more fluid passages.

Other features and aspects of this disclosure will be apparent from the following description and the accompanying drawings.

### BRIEF DESCRIPTION OF THE DRAWINGS

FIG. 1 is a schematic side view of an exemplary machine;

FIG. 2 is a block diagram of the machine of FIG. 1 depicting an electrical connector assembly, according to an example of the present disclosure;

FIG. 3 illustrates a schematic perspective view of a first connector plate of the electrical connector assembly of FIG. 2;

FIG. 4 illustrates a schematic perspective view of a second connector plate of the electrical connector assembly of FIG. 2;

FIG. 5 is a block diagram illustrating a battery system, the electrical connector assembly, and a cooling system associated with the machine of FIG. 1, according to an example of the present disclosure;

FIG. 6 illustrates a schematic front view of a connector plate that may be used with an electrical connector assembly, according to another example of the present disclosure;

FIGS. 7 illustrates a schematic side view of an electrical connector assembly having fluid connectors, according to yet another example of the present disclosure;

FIG. 8 illustrates a schematic perspective view of a first connector plate associated with the electrical connector assembly of FIG. 7, wherein the first connector plate has a cooling circuit associated therewith, according to yet another example of the present disclosure;

FIG. 9 illustrates a schematic perspective view of a second connector plate associated with the electrical connector assembly of FIG. 7, wherein the second connector plate has a cooling circuit associated therewith, according to yet another example of the present disclosure; and

FIG. 10 is a flowchart for a method of cooling an electrical connector of the machine of FIG. 1, according to an example of the present disclosure.

### DETAILED DESCRIPTION

Wherever possible, the same reference numbers will be used throughout the drawings to refer to the same or like parts.

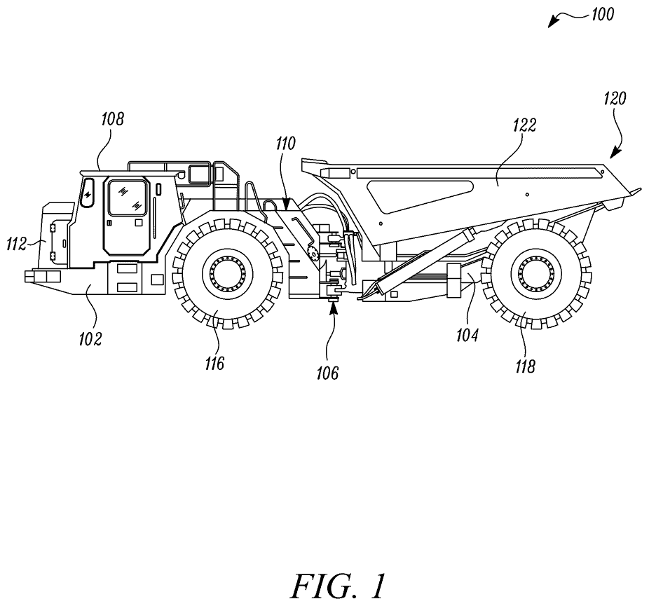

Referring to FIG. 1, an exemplary machine 100 is illustrated. As shown in FIG. 1, the machine 100 is embodied as an earthmoving machine i.e., an underground articulated truck. However, embodiments disclosed herein are not limited to a type of machine used. Rather, other types of machines, including but not limited to, mobile and/or stationary machines, or other earthmoving machines, for example, pavers, cranes, excavators, dozers, graders, or mining trucks may be used as the machine 100 in lieu of the articulated truck disclosed herein to realize embodiments of the present disclosure.

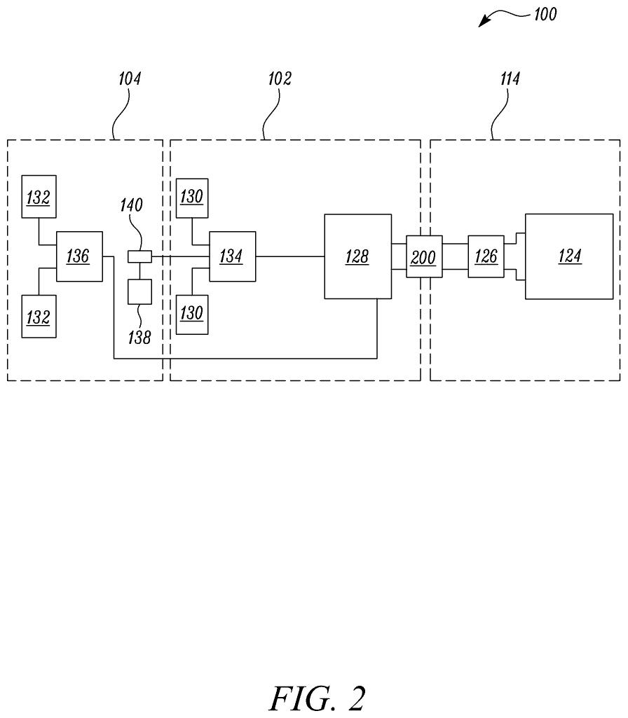

As shown in FIG. 1, the machine 100 includes a front frame 102 and a rear frame 104. An articulation assembly 106 of the machine 100 couples the front frame 102 and the rear frame 104. The front frame 102 may support various components of the machine 100 thereon. The machine 100 includes an operator cabin 108. Further, the machine 100 also includes a platform 110. The machine 100 further includes an enclosure 112 defined by the front frame 102. The machine 100 further includes a battery system 114 (shown in FIG. 2) that provides operating power to the machine 100. The battery system 114 is disposed within the enclosure 112. Thus, the front frame 102 supports the operator cabin 108, the platform 110, and the battery system 114. The front frame 102 further supports a pair of front wheels 116 of the machine 100.

Further, the rear frame 104 supports a pair of rear wheels 118 of the machine 100. The machine 100 also includes a material handling system 120 supported by the rear frame 104. The material handling system 120 includes a receptacle 122. The receptacle 122 may receive and carry materials, such as, dirt, rock, dirt, gravels, construction materials, and the like, without any limitations. The receptacle 122 may be pivotable with respect to the rear frame 104.

Referring now to FIG. 2, the battery system 114 includes one or battery modules 124. Further, the battery system 114 includes a power distribution unit (PDU) 126. The battery modules 124 may provide a desired amount of power output and voltage output. In some examples, each battery module 124 may embody a high-voltage battery module and may include one or more battery cells (not shown), such as, lithium titanate battery cells. The battery cells store electrical power and distribute the stored electrical power at the desired amount of power output and voltage output. It should be noted that the power distribution and power storage characteristics of the battery system 114 may be defined at least in part on the configurations of the one or more battery cells included in the battery modules 124. In some examples, the battery module 124 may incorporate any other type of battery technology. In other examples, the battery module 124 may be replaced by a fuel cell, an engine, such as, an internal combustion engine, and the like.

The machine 100 also includes an electrical connector assembly 200 for establishing an electrical connection. The electrical connector assembly 200 includes a high-voltage quick connector herein. The electrical connector assembly 200 is coupled with an electrical component 114. The machine 100 includes the electrical component 114. The electrical component 114 includes the battery system 114 herein. The battery system 114 will be hereinafter interchangeably referred to as “electrical component 114”.

The electrical connector assembly 200 electrically connects the battery system 114 with a power distribution unit (PDU) 128 of the machine 100. It should be noted that the electrical connector assembly 200 may be disposed between power source of any type and the PDU 128. The battery system 114 is embodied as a primary battery system of the machine 100 that supplies operating power to various components of the machine 100, via the PDU 128. As shown in FIG. 2, the PDU 128 is connected to traction motors 130 associated with each front wheel 116 (see FIG. 1), via a first inverter 134. The PDU 128 is also connected to traction motors 132 associated with each rear wheel 118 (see FIG. 1), via a second inverter 136. The machine 100 further includes a secondary battery 138 connected to the first inverter 134, via an inductor 140. The secondary battery 138 may provide power to machine components, such as, a lighting system (not shown) of the machine 100, without any limitations.

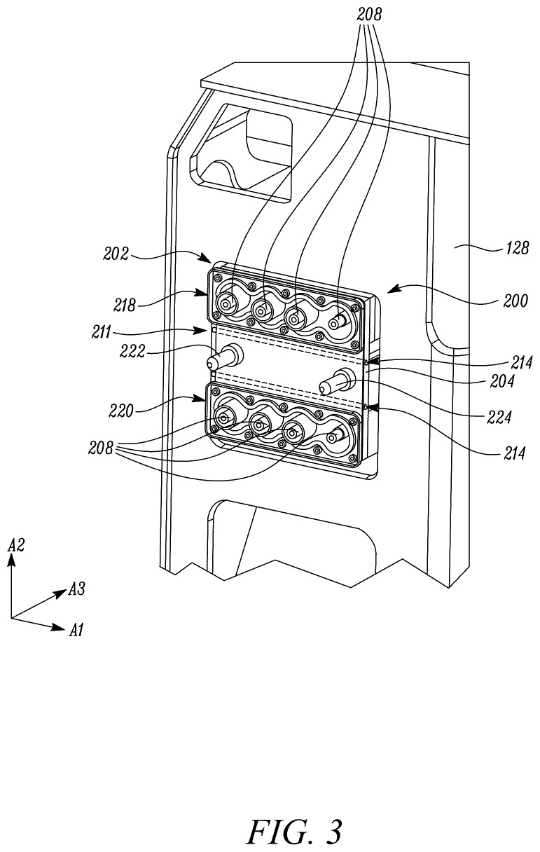

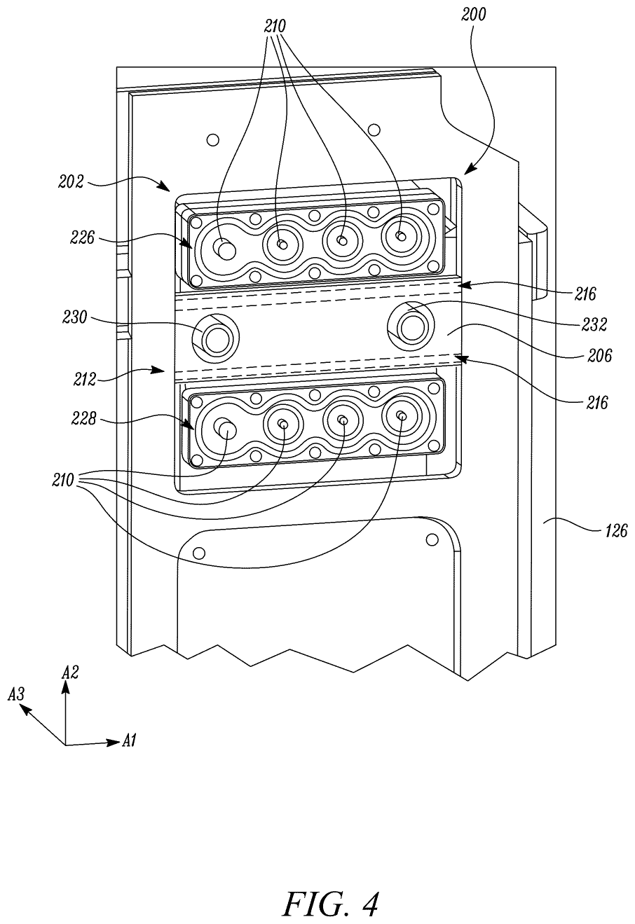

Referring now to FIGS. 3 and 4, the electrical connector assembly 200 includes an electrical connector 202 to couple with the electrical component 114 (see FIG. 2). The electrical connector 202 includes one or more connector plates 204, 206. The one or more connector plates 204, 206 extend along each of a longitudinal axis A1, a vertical axis A2, and a lateral axis A3. The one or more connector plates 204, 206 include a number of connecting terminals 208, 210 disposed in the one or more connector plates 204, 206. The one or more connector plates 204, 206 include a first connector plate 204 and a complementary, second connector plate 206 connected to the first connector plate 204. The connector plate 204 may be interchangeably referred to as “first connector plate 204” and the connector plate 206 may be interchangeably referred to as “second connector plate 206”. The first connector plate 204 may be connected to the PDU 128 (see FIG. 2) of the machine 100 (see FIGS. 1 and 2). The second connector plate 206 may be connected to the battery system 114. Specifically, the second connector plate 206 may be connected to the PDU 126 (see FIG. 2) of the battery system 114.

The electrical connector assembly 200 further includes a cooling circuit 211, 212 disposed around one or more of the number of connecting terminals 208, 210. The cooling circuit 211, 212 includes one or more fluid passages 214, 216. The one or more fluid passages 214, 216 receive a fluid flow to cool the one or more connector plates 204, 206. The fluid flow may include a coolant flow for cooling the electrical connector assembly 200. A temperature of the fluid flow may be at least below ambient temperature. The one or more fluid passages 214, 216 are defined in the one or more connector plates 204, 206. Further, in the illustrated examples of FIGS. 3 and 4, the one or more fluid passages 214, 216 extend only along the longitudinal axis A1.

Referring to FIG. 3, the first connector plate 204 includes a first set of connecting terminals 218 and a second set of connecting terminals 220 spaced apart from the first set of connecting terminals 218 along the vertical axis A2. The first set of connecting terminals 218 includes the number of connecting terminals 208 and the second set of connecting terminals 220 includes the number of connecting terminals 208. The first set of connecting terminals 218 includes four connecting terminals 208 and the second set of connecting terminals 220 includes four connecting terminals 208. The first connector plate 204 also includes a pair of guide pins 222, 224 disposed between the first and second set of connecting terminals 218, 220. The guide pins 222, 224 are spaced apart from each other along the longitudinal axis A1.

Further, the first connector plate 204 includes the cooling circuit 211 disposed around each of the first and second set of connecting terminals 218, 220. The cooling circuit 211 includes the fluid passages 214. Specifically, the first connector plate 204 includes two fluid passages 214. One fluid passage 214 is disposed proximal to the first set of connecting terminals 218. Specifically, the fluid passage 214 is disposed between the first set of connecting terminals 218 and the guide pins 222, 224. Further, the other fluid passage 214 is disposed proximal to the second set of connecting terminals 220. Specifically, the fluid passage 214 is disposed between the second set of connecting terminals 220 and the guide pins 222, 224. The fluid flow enters the fluid passages 214 via one end of the first connector plate 204 and exits the fluid passages 214 via an opposing end of the first connector plate 204.

In some examples, the first connector plate 204 may include an additional fluid passage (not shown herein) extending along the longitudinal axis A1 and disposed above the first set of connecting terminals 218. In some examples, the first connector plate 204 may include an additional fluid passage (not shown herein) extending along the longitudinal axis A1 and disposed below the second set of connecting terminals 220. In some examples, the first connector plate 204 may include additional fluid passages (not shown herein) extending along the vertical axis A2.

Referring now to FIG. 4, the second connector plate 206 includes a third set of connecting terminals 226 and a fourth set of connecting terminals 228 spaced apart from the third set of connecting terminals 226 along the vertical axis A2. The third set of connecting terminals 226 includes the number of connecting terminals 210 and the fourth set of connecting terminals 228 includes the number of connecting terminals 210. The third set of connecting terminals 226 includes four connecting terminals 210 and the fourth set of connecting terminals 228 includes four connecting terminals 210. The connecting terminals 208 (see FIG. 3) of the first set of connecting terminals 218 (see FIG. 3) connect with the connecting terminals 210 of the third set of connecting terminals 226 to establish electrical connectivity. Further, the connecting terminals 210 (see FIG. 3) of the second set of connecting terminals 220 (see FIG. 3) connect with the connecting terminals 210 of the fourth set of connecting terminals 228 to establish electrical connectivity.

The second connector plate 206 includes a pair of receptors 230, 232 disposed between the third and fourth set of connecting terminals 226, 228. The receptors 230, 232 are spaced apart from each other along the longitudinal axis A1. Each receptor 230, 232 receives a corresponding guide pin 222, 224 (see FIG. 3), when the first connector plate 204 (see FIG. 3) is connected to the second connector plate 206.

Further, the second connector plate 206 includes the cooling circuit 212 disposed around each of the third and fourth set of connecting terminals 226, 228. The cooling circuit 212 includes the fluid passages 216. Specifically, the second connector plate 206 includes two fluid passages 216. One fluid passage 216 is disposed proximal to the third set of connecting terminals 226. Specifically, the fluid passage 216 is disposed between the third set of connecting terminals 226 and the receptors 230, 232. Further, the other fluid passage 216 is disposed proximal to the fourth set of connecting terminals 228. Specifically, the fluid passage 216 is disposed between the fourth set of connecting terminals 228 and the receptors 230, 232. The fluid flow enters the fluid passages 216 via one end of the second connector plate 206 and exits the fluid passages 216 via an opposing end of the second connector plate 206.

In some examples, the second connector plate 206 may include an additional fluid passage (not shown herein) extending along the longitudinal axis A1 and disposed above the third set of connecting terminals 226. In some examples, the second connector plate 206 may include an additional fluid passage (not shown herein) extending along the longitudinal axis A1 and disposed below the fourth set of connecting terminals 228. In some examples, the second connector plate 206 may include additional fluid passages (not shown herein) extending along the vertical axis A2.

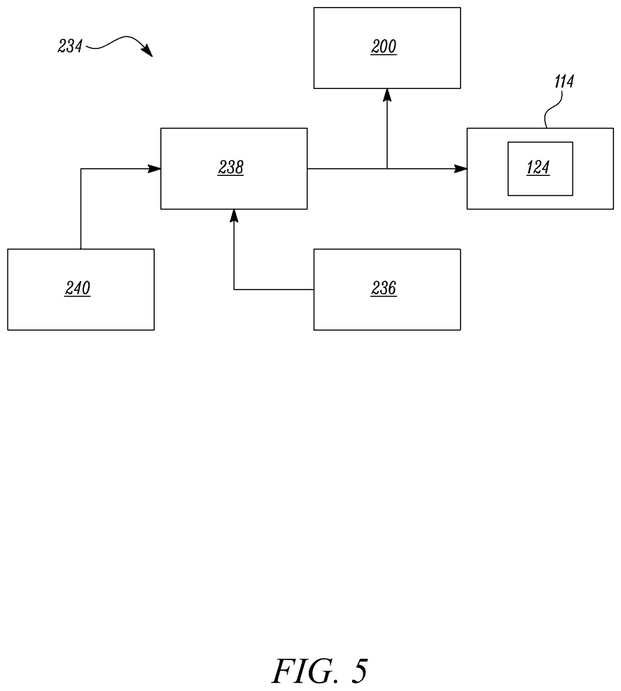

Referring now to FIG. 5, the electrical connector assembly 200 further includes a cooling system 234 that selectively supplies the fluid flow towards the one or more fluid passages 214, 216 (see FIGS. 3 and 4, respectively). The cooling system 234 described herein cools the electrical connector assembly 200 as well as the battery system 114. For example, the cooling system 234 may maintain a temperature of the battery modules 124 within desired limits. In the illustrated example of FIG. 5, the cooling system 234 includes a liquid-cooled assembly that uses coolant flow to cool the electrical connector assembly 200 and the battery system 114. Alternatively, the cooling system 234 may include an air-cooled system that may direct cooling airflow to cool the electrical connector assembly 200 and the battery system 114.

The cooling system 234 includes a fluid tank 236. The fluid tank 236 holds coolant therein. The cooling system 234 also includes a pump 238 that provides fluid communication between the fluid tank 236 and the one or more fluid passages 214, 216. Further, the pump 238 also provides fluid communication between the fluid tank 236 and the battery system 114. The cooling system 234 further includes a controller 240 communicably coupled with the pump 238.

The controller 240 may include one or more processors and one or more memories. Numerous commercially available microprocessors may perform the functions of the processors. Each processor may further include a general processor, a central processing unit, an application specific integrated circuit (ASIC), a digital signal processor, a field programmable gate array (FPGA), a digital circuit, an analog circuit, a microcontroller, any other type of processor, or any combination thereof. Each processor may include one or more components that may be operable to execute computer executable instructions or computer code that may be stored and retrieved from the memories.

The controller 240 controls the pump 238 to selectively supply the fluid flow from the fluid tank 236 towards the one or more fluid passages 214, 216. Specifically, when the battery system 114 is to be swapped/replaced with another battery system, the controller 240 may send a control signal to operate the pump 238 in order to direct the fluid towards the fluid passages 214, 216 for cooling the electrical connector assembly 200.

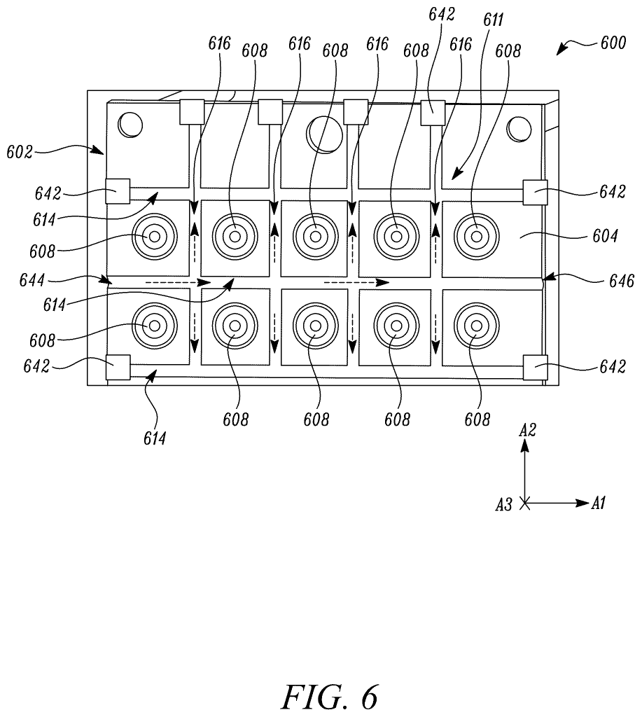

FIG. 6 illustrates another exemplary electrical connector assembly 600. The electrical connector assembly 600 may be similar in functionality to the electrical connector 202 of FIGS. 3 and 4. The electrical connector assembly 600 includes an electrical connector 602. The electrical connector 602 includes a connector plate 604 and a number of connecting terminals 608. Specifically, the electrical connector 602 includes ten connecting terminals 608 herein.

The electrical connector assembly 600 further includes a cooling circuit 611 disposed around one or more of the number of connecting terminals 608. The cooling circuit 611 includes one or more fluid passages 614, 616. The one or more fluid passages 614, 616 receive a fluid flow to cool the connector plate 604. The fluid flow is received from the cooling system 234 explained in relation to FIG. 5. The one or more fluid passages 614, 616 are defined in the connector plate 604. The one or more fluid passages 614, 616 extend along the longitudinal axis A1 and the vertical axis A2. Specifically, the connector plate 604 includes three fluid passages 614 extending along the longitudinal axis A1. Further, the connector plate 604 includes four fluid passages 616 extending along the vertical axis A2. The connector plate 604 includes a number of port plugs 642 that prevent a run-out of the fluid flow from the fluid passages 614, 616. The fluid flow enters the connector plate 604 through a first end 644 of the fluid passage 614 and flows through the fluid passages 614, 616, thereby cooling the connecting terminals 608. Further, the fluid flow exits the connector plate 604 through a second end 646 of the fluid passage 614. A direction of the fluid flow is illustrated using arrows in FIG. 6.

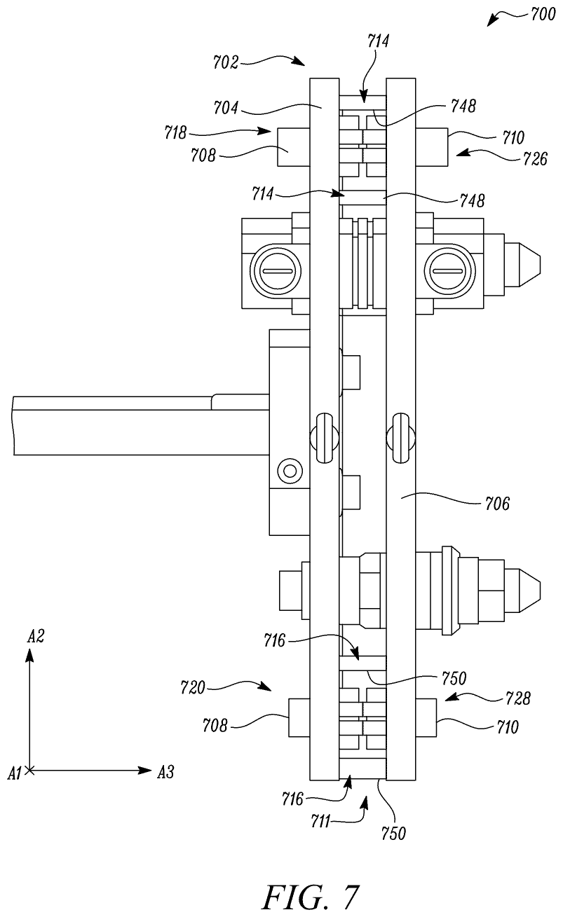

FIG. 7 illustrates an electrical connector assembly 700, according to another example of the present disclosure. The electrical connector assembly 700 includes an electrical connector 702 to couple with the electrical component 114 (see FIG. 2). The electrical connector 702 includes one or more connector plates 704, 706. The one or more connector plates 704, 706 extend along each of a longitudinal axis A1, a vertical axis A2, and a lateral axis A3. The one or more connector plates 704, 706 include a number of connecting terminals 708, 710 disposed in the one or more connector plates 704, 706. The one or more connector plates 704, 706 include a first connector plate 704 and a complementary, second connector plate 706 connected to the first connector plate 704. The first connector plate 704 may be connected to the PDU 128 (see FIG. 1) of the machine 100 (see FIGS. 1 and 2). The second connector plate 706 may be connected to the battery system 114. Specifically, the second connector plate 706 may be connected to the PDU 126 (see FIG. 2) of the battery system 114. The connector plate 704 may be interchangeably referred to as “first connector plate 704” and the connector plate 706 may be interchangeably referred to as “second connector plate 706”.

The electrical connector assembly 700 further includes a cooling circuit 711 disposed around one or more of the number of connecting terminals 708, 710. The cooling circuit 711 includes one or more fluid connectors 748, 750 extending along the lateral axis A3 between the first connector plate 704 and the second connector plate 706. In the illustrated example of FIG. 7, the cooling circuit 711 includes two fluid connectors 748 disposed proximal to a first set of connecting terminals 718 and a third set of connecting terminals 726. Further, the cooling circuit 711 includes two fluid connectors 750 disposed proximal to a second set of connecting terminals 720 and a fourth set of connecting terminals 728. The fluid connectors 748, 750 may include any known in the art fluid connection device that establishes fluid communication between the first and second connector plates 704, 706.

The cooling circuit 711 includes one or more fluid passages 714, 716. In the illustrated example of FIG. 7, the one or more fluid passages 714, 716 include the one or more transverse fluid passages 714, 716 defined by the one or more fluid connectors 748, 750. Specifically, each fluid connector 748 defines the corresponding transverse fluid passages 714 and each fluid connector 750 defines the corresponding transverse fluid passages 716. The one or more fluid passages 714, 716 receive a fluid flow to cool the one or more connector plates 704, 706. The fluid flow is received from the cooling system 234 explained in relation to FIG. 5. In some examples, the fluid flow may enter the transverse fluid passages 714, 716 via the first connector plate 704 and the fluid flow may exit the transverse fluid passages 714, 716 via the second connector plate 706. In other examples, the fluid flow may enter the transverse fluid passages 714, 716 via the second connector plate 706 and the fluid flow may exit the transverse fluid passages 714, 716 via the first connector plate 704. Accordingly, the first and second connector plates 704, 706 may include openings (not shown herein) therein to allow entry and exit of the fluid flow.

It should be noted that, in addition to the transverse fluid passages 714, 716, each of the first and second connector plates 704, 706 may also include one or more fluid passages (such as the fluid passages 214, 216, 614, 616 of FIGS. 3, 4, and 6) that may extend along the longitudinal axis A1 and/or the vertical axis A2.

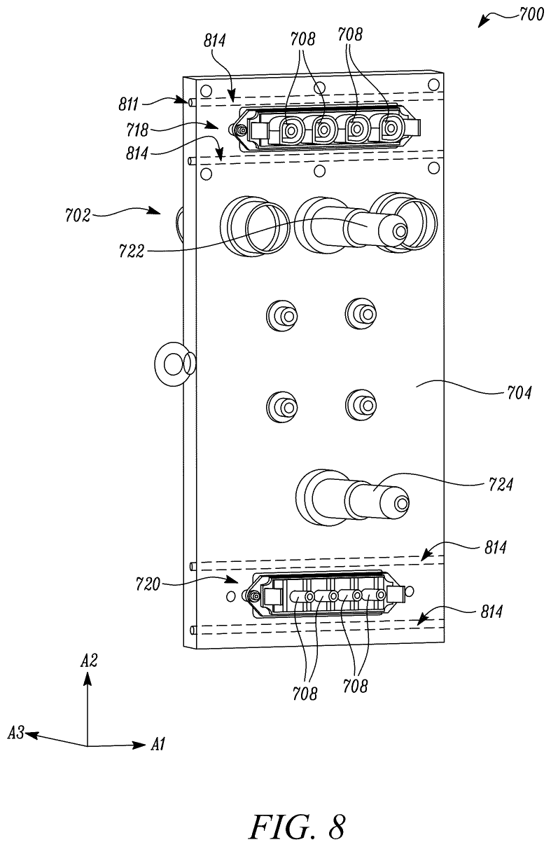

Referring to FIG. 8, the first connector plate 704 includes a first set of connecting terminals 718 and a second set of connecting terminals 720 spaced apart from the first set of connecting terminals 718 along the vertical axis A2. The first set of connecting terminals 718 includes the number of connecting terminals 708 and the second set of connecting terminals 720 includes the number of connecting terminals 708. The first set of connecting terminals 718 includes four connecting terminals 708 and the second set of connecting terminals 720 includes four connecting terminals 708. The first connector plate 704 also includes a pair of guide pins 722, 724 disposed between the first and second set of connecting terminals 718, 720. The guide pins 722, 724 are spaced apart from each other along the vertical axis A2. The guide pin 722 is disposed proximal to the first set of connecting terminals 718 and the guide pin 724 is disposed proximal to the second set of connecting terminals 720.

Further, the first connector plate 704 includes the cooling circuit 811 disposed around each of the first and second set of connecting terminals 718, 720. The cooling circuit 811 includes the fluid passages 814. Specifically, the first connector plate 704 includes four fluid passages 814. Two of the fluid passages 814 are disposed proximal to the first set of connecting terminals 718. Specifically, one fluid passage 814 is disposed between the first set of connecting terminals 718 and the guide pin 722 and the other fluid passage 814 is disposed above the first set of connecting terminal 718. Further, the other two fluid passages 814 are disposed proximal to the second set of connecting terminals 720. Specifically, the fluid passage 814 is disposed between the second set of connecting terminals 720 and the guide pin 724 and the other fluid passage 814 is disposed above the second set of connecting terminal 720. The fluid flow enters the fluid passages 814 via one end of the first connector plate 704 and exits the fluid passages 814 via an opposing end of the first connector plate 704. In some examples, the first connector plate 704 may include additional fluid passages (not shown herein) extending along the vertical axis A2.

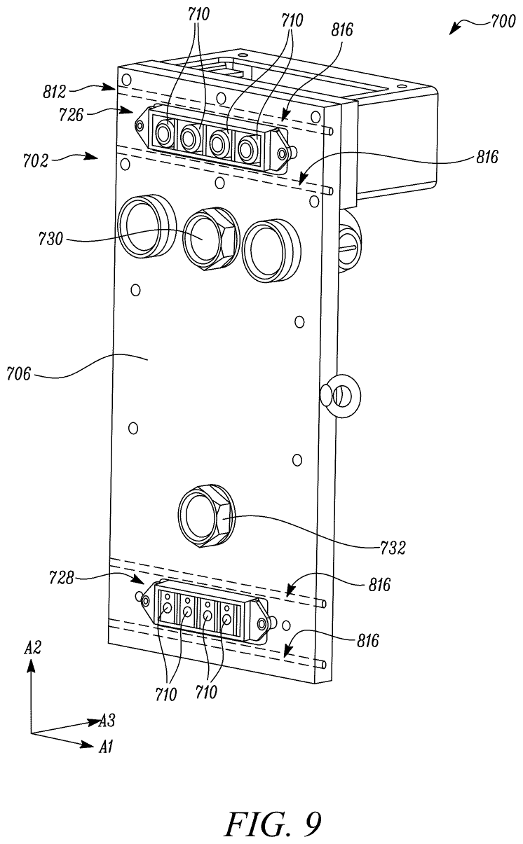

Referring now to FIG. 9, the second connector plate 706 includes a third set of connecting terminals 726 and a fourth set of connecting terminals 728 spaced apart from the third set of connecting terminals 726 along the vertical axis A2. The third set of connecting terminals 726 includes the number of connecting terminals 710 and the fourth set of connecting terminals 728 includes the number of connecting terminals 710. The third set of connecting terminals 726 includes four connecting terminals 710 and the fourth set of connecting terminals 728 includes four connecting terminals 710. The connecting terminals 708 (see FIG. 8) of the first set of connecting terminals 718 (see FIG. 8) connect with the connecting terminals 710 of the third set of connecting terminals 726 to establish electrical connectivity. Further, the connecting terminals 710 (see FIG. 8) of the second set of connecting terminals 720 (see FIG. 8) connect with the connecting terminals 710 of the fourth set of connecting terminals 728 to establish electrical connectivity.

The second connector plate 706 includes a pair of receptors 730, 732 disposed between the third and fourth set of connecting terminals 728. The receptor 730 is disposed proximal to the third set of connecting terminals 726 and the receptor 732 is disposed proximal to the fourth set of connecting terminals 728. The receptors 730, 732 are spaced apart from each other along the vertical axis A2. Each receptor 730, 732 receives a corresponding guide pin 722, 724 (see FIG. 8), when the first connector plate 704 (see FIG. 8) is connected to the second connector plate 706.

Further, the second connector plate 706 includes the cooling circuit 812 disposed around each of the third and fourth set of connecting terminals 728. The cooling circuit 812 includes the fluid passages 816. Specifically, the second connector plate 706 includes four fluid passages 816. The fluid passages 816 are disposed proximal to the third set of connecting terminals 726. Specifically, one fluid passage 816 is disposed between the third set of connecting terminals 726 and the receptor 730 and the other fluid passage 816 is disposed above the third set of connecting terminal 726. Further, the fluid passages 816 are disposed proximal to the fourth set of connecting terminals 728. Specifically, one fluid passage 816 is disposed between the fourth set of connecting terminals 728 and the receptor 732 and the other fluid passage 816 is disposed above the fourth set of connecting terminal 728. The fluid flow enters the fluid passages 816 via one end of the second connector plate 706 and exits the fluid passages 816 via an opposing end of the second connector plate 706. In some examples, the second connector plate 706 may include additional fluid passages (not shown herein) extending along the vertical axis A2.

It is to be understood that individual features shown or described for one embodiment may be combined with individual features shown or described for another embodiment. The above described implementation does not in any way limit the scope of the present disclosure. Therefore, it is to be understood although some features are shown or described to illustrate the use of the present disclosure in the context of functional segments, such features may be omitted from the scope of the present disclosure without departing from the spirit of the present disclosure as defined in the appended claims.

### Industrial Applicability

The present disclosure is directed towards the electrical connector assembly 200, 600, 700 that includes the cooling circuit 211, 212, 611, 612, 711, 811, 812 associated therewith. The cooling circuit 211, 212, 611, 612, 711, 811, 812 is supplied with the fluid flow during a swapping procedure of the battery system 114. It should be noted that the cooling circuit 211, 212, 611, 612, 711, 811, 812 may be supplied with the fluid flow during other operations, without any limitations. The fluid flow flowing through the electrical connector assembly 200, 600, 700 may reduce a temperature of the electrical connector assembly 200, 600, 700 below ambient temperature. Specifically, the cooling circuit 211, 212, 611, 612, 711, 811, 812 is disposed around the connecting terminals 208, 210, 608, 610, 708, 710 as such interface components tend to heat up/generate heat as they conduct power during charging/discharging. Further, the cooling circuit 211, 212, 611, 612, 711, 811, 812 receives the fluid flow from the cooling system 234 that also facilitates cooling of the battery system 114. Thus, the cooling circuit 211, 212, 611, 612, 711, 811, 812 described herein does not require separate components to facilitate cooling of the electrical connector assembly 200, 600, 700.

The cooling circuit 211, 212, 611, 612, 711, 811, 812 associated with the electrical connector assembly 200, 600, 700 is simple in construction and is cost-effective. Further, the pump 238 of the cooling system 234 may be selectively operated, via the controller 240, so as to supply the fluid flow towards the cooling circuit 211, 212, 611, 612, 711, 811, 812. For example, the pump 238 may be selectively operated to supply the fluid flow to the cooling circuit 211, 212, 611, 612, 711, 811, 811, 812 as and when required. For example, the pump 238 may be operated only during the swapping procedure of the battery system 114. The cooling circuit 211, 212, 611, 612, 711, 811, 812 may allow cooling of the electrical connector assembly 200, 600, 700 in a time efficient manner. Further, the cooling circuit 211, 212, 611, 612, 711, 811, 812 may be incorporated into different types/designs of electrical connector assemblies other than those explained in this disclosure.

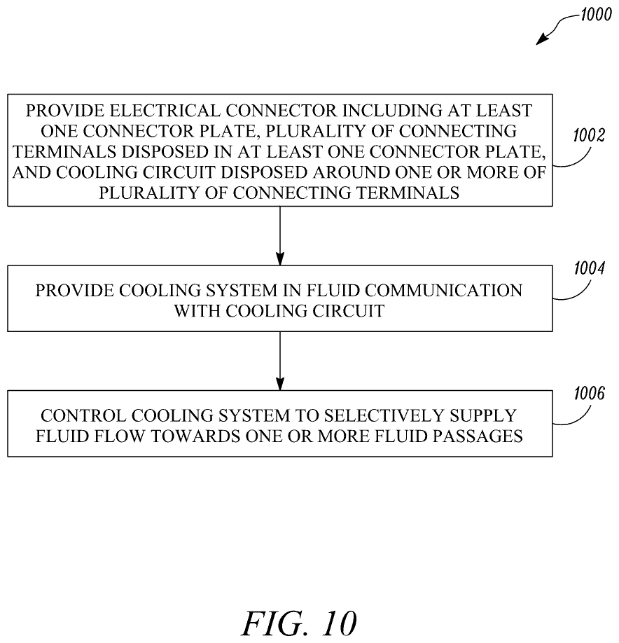

FIG. 10 is a flowchart for a method 1000 of cooling the electrical connector 202, 602, 702 of the machine 100. With reference to FIGS. 1 to 10, the electrical connector 202, 602, 702 is to be coupled with the electrical component 114 of the machine 100. The electrical component 114 includes the battery system 114.

At step 1002, the electrical connector 202, 602, 702 is provided. The electrical connector 202, 602, 702 includes the one or more connector plates 204, 206, 604, 606, 704, 706, the number of connecting terminals 208, 210, 608, 610, 708, 710 disposed in the one or more connector plates 204, 206, 604, 606, 704, 706, and the cooling circuit 211, 212, 611, 612, 711, 811, 812 disposed around the one or more of the number of connecting terminals 208, 210, 608, 610, 708, 710. The cooling circuit 211, 212, 611, 612, 711, 811, 812 includes the one or more fluid passages 214, 216, 614, 616, 714, 716, 814, 816. The one or more fluid passages 214, 216, 614, 616, 714, 716, 814, 816 receive the fluid flow to cool the one or more connector plates 204, 206, 604, 606, 704, 706. At step 1004, the cooling system 234 is provided in fluid communication with the cooling circuit 211, 212, 611, 612, 711, 811, 812. At step 1006, the cooling system 234 is controlled to selectively supply the fluid flow towards the one or more fluid passages 214, 216, 614, 616, 714, 716, 814, 816.

In some examples, the one or more fluid passages 214, 216, 614, 616, 814, 816 are defined in the one or more connector plates 204, 206, 604, 606, 704, 706. The one or more connector plates 204, 206, 604, 606, 704, 706 extend along each of the longitudinal axis A1, the vertical axis A2, and the lateral axis A3. In some examples, the one or more fluid passages 214, 216, 614, 616, 814, 816 extend along one or more of the longitudinal axis A1 and the vertical axis A2.

In some examples, the one or more connector plates 704, 706 include the first connector plate 704 and the second connector plate 706 connected to the first connector plate 704. The cooling circuit 711 includes the one or more fluid connectors 748, 750 extending along the lateral axis A3 between the first connector plate 704 and the second connector plate 706. The one or more fluid passages 714, 716 include the one or more transverse fluid passages 714, 716 defined by the one or more fluid connectors 748, 750.

The method 1000 further includes a step at which the fluid tank 236 of the cooling system 234 is fluidly communicated with the one or more fluid passages 214, 216, 614, 616, 714, 716, 814, 816, via the pump 238 of the cooling system 234. The method 1000 further includes a step at which the controller 240 of the cooling system 234 controls the pump 238 to selectively supply the fluid flow from the fluid tank 236 towards the one or more fluid passages 214, 216, 614, 616, 714, 716, 814, 816.

While aspects of the present disclosure have been particularly shown and described with reference to the embodiments above, it will be understood by those skilled in the art that various additional embodiments may be contemplated by the modification of the disclosed machine, systems and methods without departing from the spirit and scope of the disclosure. Such embodiments should be understood to fall within the scope of the present disclosure as determined based upon the claims and any equivalents thereof.

1. An electrical connector assembly for establishing an electrical connection, the electrical connector assembly comprising:
an electrical connector adapted to couple with an electrical component, the electrical connector comprising:
at least one connector plate;
a plurality of connecting terminals disposed in the at least one connector plate; and
a cooling circuit disposed around one or more of the plurality of connecting terminals, wherein the cooling circuit includes one or more fluid passages, and wherein the one or more fluid passages are adapted to receive a fluid flow to cool the at least one connector plate.

2. The electrical connector assembly of claim 1, wherein the one or more fluid passages are defined in the at least one connector plate.

3. The electrical connector assembly of claim 2, wherein the at least one connector plate extends along each of a longitudinal axis, a vertical axis, and a lateral axis, and wherein the one or more fluid passages extends along at least one of the longitudinal axis and the vertical axis.

4. The electrical connector assembly of claim 1, wherein the at least one connector plate includes a first connector plate and a second connector plate connected to the first connector plate.

5. The electrical connector assembly of claim 4, wherein the cooling circuit includes one or more fluid connectors extending along a lateral axis between the first connector plate and the second connector plate, and wherein the one or more fluid passages include one or more transverse fluid passages defined by the one or more fluid connectors.

6. The electrical connector assembly of claim 1, wherein the electrical component includes a battery system.

7. The electrical connector assembly of claim 1, further comprising a cooling system adapted to selectively supply the fluid flow towards the one or more fluid passages.

8. The electrical connector assembly of claim 7, wherein the cooling system includes:
a fluid tank;
a pump adapted to provide fluid communication between the fluid tank and the one or more fluid passages; and
a controller communicably coupled with the pump, wherein the controller is configured to control the pump to selectively supply the fluid flow from the fluid tank towards the one or more fluid passages.

9. A machine comprising:
an electrical component;
an electrical connector coupled with the electrical component, the electrical connector including:
at least one connector plate;
a plurality of connecting terminals disposed in the at least one connector plate; and
a cooling circuit disposed around one or more of the plurality of connecting terminals, wherein the cooling circuit includes one or more fluid passages, and wherein the one or more fluid passages are adapted to receive a fluid flow to cool the at least one connector plate; and
a cooling system in fluid communication with the cooling circuit, wherein the cooling system is adapted to selectively supply the fluid flow towards the one or more fluid passages.

10. The machine of claim 9, wherein the one or more fluid passages are defined in the at least one connector plate.

11. The machine of claim 10, wherein the at least one connector plate extends along each of a longitudinal axis, a vertical axis, and a lateral axis, and wherein the one or more fluid passages extends along at least one of the longitudinal axis and the vertical axis.

12. The machine of claim 9, wherein the at least one connector plate includes a first connector plate and a second connector plate connected to the first connector plate.

13. The machine of claim 12, wherein the cooling circuit includes one or more fluid connectors extending along a lateral axis between the first connector plate and the second connector plate, and wherein the one or more fluid passages include one or more transverse fluid passages defined by the one or more fluid connectors.

14. The machine of claim 9, wherein the electrical component includes a battery system.

15. The machine of claim 9, wherein the cooling system includes:
a fluid tank;
a pump adapted to provide fluid communication between the fluid tank and the one or more fluid passages; and
a controller communicably coupled with the pump, wherein the controller is configured to control the pump to selectively supply the fluid flow from the fluid tank towards the one or more fluid passages.

16. A method of cooling an electrical connector of a machine, wherein the electrical connector is adapted to be coupled with an electrical component of the machine, the method comprising:
providing the electrical connector including at least one connector plate, a plurality of connecting terminals disposed in the at least one connector plate, and a cooling circuit disposed around one or more of the plurality of connecting terminals, wherein the cooling circuit includes one or more fluid passages, and wherein the one or more fluid passages are adapted to receive a fluid flow to cool the at least one connector plate;
providing a cooling system in fluid communication with the cooling circuit; and
controlling the cooling system to selectively supply the fluid flow towards the one or more fluid passages.

17. The method of claim 16, wherein the one or more fluid passages are defined in the at least one connector plate, wherein the at least one connector plate extends along each of a longitudinal axis, a vertical axis, and a lateral axis, and wherein the one or more fluid passages extends along at least one of the longitudinal axis and the vertical axis.

18. The method of claim 16, wherein the at least one connector plate includes a first connector plate and a second connector plate connected to the first connector plate, wherein the cooling circuit includes one or more fluid connectors extending along a lateral axis between the first connector plate and the second connector plate, and wherein the one or more fluid passages include one or more transverse fluid passages defined by the one or more fluid connectors.

19. The method of claim 16, wherein the electrical component includes a battery system.

20. The method of claim 16, further comprising:
communicating, fluidly, a fluid tank of the cooling system with the one or more fluid passages, via a pump of the cooling system; and
controlling, by a controller of the cooling system, the pump to selectively supply the fluid flow from the fluid tank towards the one or more fluid passages.
